(19) United States
(12) Patent Application Publication
(10) Pub. No.: US 2019/0181337 A1
(43) Pub. Date: Jun. 13, 2019

(54) BARRIERS FOR METAL FILAMENT MEMORY DEVICES

(71) Applicant: Intel Corporation, Santa Clara, CA (US)

(72) Inventors: Ravi Pillarisetty, Portland, OR (US); Elijah V. Karpov, Portland, OR (US); Roza Kotlyar, Portland, OR (US); Prashant Majhi, San Jose, CA (US)

(73) Assignee: Intel Corporation, Santa Clara, CA (US)

(21) Appl. No.: 16/323,602

(22) PCT Filed: Sep. 25, 2016
(86) PCT No.: PCT/US2016/053619

§ 371 Date: Feb. 6, 2019

(51) Int. Cl. H01L 45/00; H01L 27/24

(52) U.S. Cl. CPC H01L 45/085; H01L 45/1233; H01L 27/2454; H01L 45/145; H01L 45/1266

(57) ABSTRACT

Disclosed herein are metal filament memory devices (MFMDs), and related devices and techniques. In some embodiments, an MFMD may include: an electrode including an electrochemically active metal; an electrolyte; and a barrier material disposed between the electrode and the electrolyte, wherein the barrier material has a lower work function than the electrode.

### CROSS-REFERENCE TO RELATED APPLICATION

This application is a national phase entry of PCT International Application No. PCT/US2016/053619, filed Sep. 25, 2016, entitled “BARRIERS FOR METAL FILAMENT MEMORY DEVICES.” The disclosure of this prior application is incorporated by reference herein in its entirety.

### BACKGROUND

A nonvolatile random access memory (NVRAM) device is a memory device that retains its data in the absence of supplied power. Flash memory is an example of an existing NVRAM technology, but flash memory may be limited in its speed, endurance, area, and lifetime.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a cross-sectional view of an example electronic device including a memory cell having an embodiment of a metal filament memory device (MFMD) coupled to a transistor, in accordance with various embodiments.

FIG. 2 is a plot of an example energy profile along the MFMD of FIG. 1, in accordance with various embodiments.

FIGS. 3-6 illustrate various example stages in the manufacture of the MFMD of FIG. 1, in accordance with various embodiments.

FIG. 7 is a flow diagram of an illustrative method of manufacturing an MFMD, in accordance with various embodiments.

FIGS. 8A and 8B are top views of a wafer and dies that may include any of the MFMDs disclosed herein.

FIG. 9 is a cross-sectional side view of a device assembly that may include any of the MFMDs disclosed herein.

FIG. 10 is a block diagram of an example computing device that may include any of the MFMDs disclosed herein, in accordance with various embodiments.

### DETAILED DESCRIPTION

Disclosed herein are metal filament memory cells, and related devices and techniques. In some embodiments, an MFMD may include: an electrode including an electrochemically active metal; an electrolyte; and a barrier material disposed between the electrode and the electrolyte, wherein the barrier material has a lower work function than the electrode.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The disclosure may use the singular term “layer,” but the term “layer” should be understood to refer to assemblies that may include multiple different material layers. The accompanying drawings are not necessarily drawn to scale.

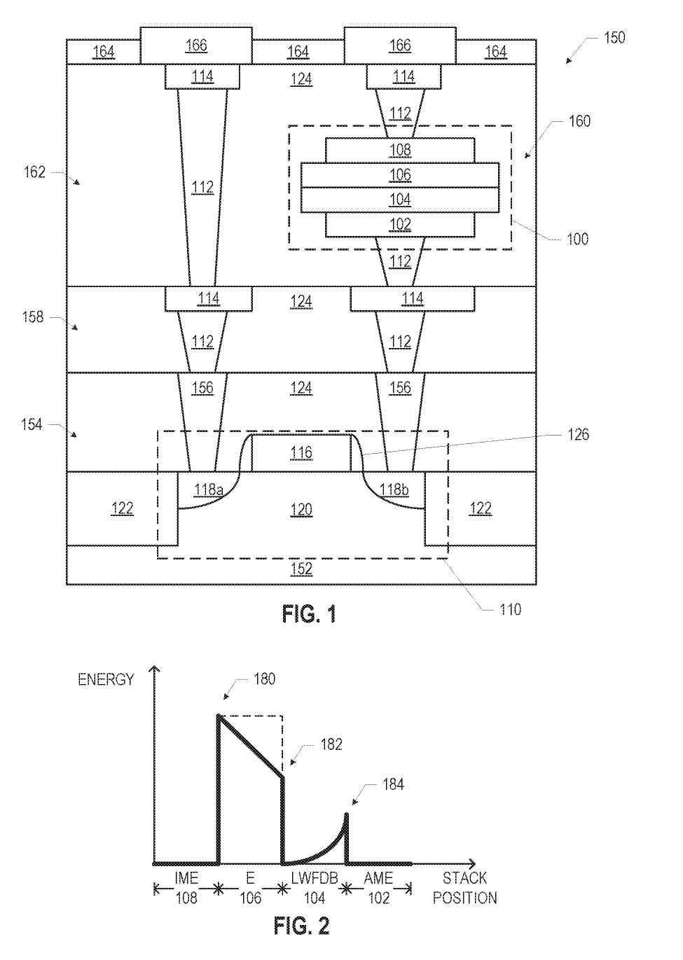

FIG. 1 is a side cross-sectional view of an example electronic device 150 including a memory cell 160 having a metal filament memory device (MFMD) 100 coupled to a transistor 110, in accordance with various embodiments. As discussed in detail below, during operation, the MFMD 100 may switch between two different nonvolatile states: a low resistance state (LRS) in which metal filaments through an electrolyte provide a conductive pathway through the MFMD 100, and a high resistance state (HRS) in which no or fewer such conductive pathways are available. In some embodiments of the MFMD 100, an initial “forming” operation may be performed to create the first conductive pathways; this forming operation may include applying a threshold “forming voltage” across the MFMD 100 to create initial filaments (e.g., after or during manufacture). The state of the MFMD 100 may be used to represent a data bit (e.g., a “1” for HRS and a “0” for LRS, or vice versa). The transistor 110 may help control the current provided to the MFMD 100 during use, as discussed below.

The electronic device 150 may be formed on a substrate 152 (e.g., the wafer 450 of FIG. 8A, discussed below) and may be included in a die (e.g., the die 452 of FIG. 8B, discussed below). The substrate 152 may be a semiconductor substrate composed of semiconductor material systems including, for example, n-type or p-type material systems. The substrate 152 may include, for example, a crystalline substrate formed using a bulk silicon or a silicon-on-insulator substructure. In some embodiments, the semiconductor substrate 152 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the substrate 152. Although a few examples of materials from which the substrate 152 may be formed are described here, any material that may serve as a foundation for an electronic device 150 may be used. The substrate 152 may be part of a singulated die (e.g., the dies 452 of FIG. 8B) or a wafer (e.g., the wafer 450 of FIG. 8A).

The electronic device 150 may include one or more device layers 154 disposed on the substrate 152. The device layer 154 may include features of one or more transistors 110 (e.g., metal oxide semiconductor field-effect transistors (MOSFETs)) formed on the substrate 152. The device layer 154 may include, for example, one or more source and/or drain (S/D) regions 118, a gate 116 to control current flow in the channel 120 of the transistors 110 between the S/D regions 118, and one or more S/D contacts 156 (which may take the form of conductive vias) to route electrical signals to/from the S/D regions 118. Adjacent transistors 110 may be isolated from each other by a shallow trench isolation (STI) insulating material 122, in some embodiments. The transistors 110 may include additional features not depicted for the sake of clarity, such as device isolation regions, gate contacts, and the like. The transistors 110 are not limited to the type and configuration depicted in FIG. 1 and may include a wide variety of other types and configurations such as, for example, planar transistors, nonplanar transistors, or a combination of both. Nonplanar transistors may include FinFET transistors, such as double-gate transistors or tri-gate transistors, and wrap-around or all-around gate transistors, such as nanoribbon and nanowire transistors.

Each transistor 110 may include a gate 116 formed of at least two layers, a gate dielectric layer and a gate electrode layer. The gate electrode layer may include at least one p-type work function metal or n-type work function metal, depending on whether the transistor 110 is to be a p-type metal oxide semiconductor (PMOS) transistor or an n-type metal oxide semiconductor (NMOS) transistor. For a PMOS transistor, metals that may be used for the gate electrode layer may include, but are not limited to, ruthenium, palladium, platinum, cobalt, nickel, and conductive metal oxides (e.g., ruthenium oxide). For an NMOS transistor, metals that may be used for the gate electrode layer include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode layer may consist of a stack of two or more metal layers, where one or more metal layers are work function metal layers and at least one metal layer is a fill metal layer. Further metal layers may be included for other purposes, such as to act as a barrier layer. The gate dielectric layer may be, for example, silicon oxide, aluminum oxide, or a high-k dielectric, such as hafnium oxide. More generally, the gate dielectric layer may include elements such as hafnium, silicon, oxygen, titanium, tantalum, lanthanum, aluminum, zirconium, barium, strontium, yttrium, lead, scandium, niobium, and zinc. Examples of materials that may be used in the gate dielectric layer may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric layer to improve the quality of the gate dielectric layer.

In some embodiments, when viewed as a cross section of the transistor 110 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar non-U-shaped structures. For example, the gate electrode may consist of one or more U-shaped metal layers formed atop one or more planar non-U-shaped layers. In some embodiments, the gate electrode may consist of a V-shaped structure.

In some embodiments, a pair of sidewall spacers 126 may be formed on opposing sides of the gate 116 to bracket the gate stack. The sidewall spacers 126 may be formed from a material such as silicon nitride, silicon oxide, silicon carbide, silicon nitride doped with carbon, and silicon oxynitride. Processes for forming sidewall spacers 126 are well known in the art and generally include deposition and etching process steps. In some embodiments, multiple pairs of sidewall spacers 126 may be used; for instance, two pairs, three pairs, or four pairs of sidewall spacers 126 may be formed on opposing sides of the gate stack.

The S/D regions 118 may be formed within the substrate 152 adjacent to the gate 116 of each transistor 110. For example, the S/D regions 118 may be formed using either an implantation/diffusion process or a deposition process. In the former process, dopants such as boron, aluminum, antimony, phosphorous, or arsenic may be ion-implanted into the substrate 152 to form the S/D regions 118. An annealing process that activates the dopants and causes them to diffuse farther into the substrate 152 may follow the ion implantation process. In the latter process, an epitaxial deposition process may provide material that is used to fabricate the S/D regions 118. In some implementations, the S/D regions 118 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 118 may be formed using one or more alternate semiconductor materials such as germanium or a group III-V material or alloy. In further embodiments, one or more layers of metal and/or metal alloys may be used to form the S/D regions 118. In some embodiments, an etch process may be performed before the epitaxial deposition to create recesses in the substrate 152 in which the material for the S/D regions 118 is deposited.

Electrical signals, such as power and/or input/output (I/O) signals, may be routed to and/or from the transistors 110 of the device layer 154 through one or more interconnect layers disposed on the device layer 154 (illustrated in FIG. 1 as interconnect layers 158 and 162). For example, electrically conductive features of the device layer 154 (e.g., the gate 116 and the S/D contacts 156) may be electrically coupled with the interconnect structures including conductive vias 112 and/or conductive lines 114 of the interconnect layers 158 and 162. The one or more interconnect layers 158 and 162 may form an interlayer dielectric (ILD) stack of the electronic device 150.

The interconnect structures may be arranged within the interconnect layers 158 and 162 to route electrical signals according to a wide variety of designs (in particular, the arrangement is not limited to the particular configuration of interconnect structures depicted in FIG. 1). Although a particular number of interconnect layers is depicted in FIG. 1, embodiments of the present disclosure include electronic devices having more or fewer interconnect layers than depicted.

In some embodiments, the interconnect structures may include conductive lines 114 (sometimes referred to as “trench structures”) and/or conductive vias 112 (sometimes referred to as “holes”) filled with an electrically conductive material such as a metal. The conductive lines 114 may be arranged to route electrical signals in a direction of a plane that is substantially parallel with a surface of the substrate 152 upon which the device layer 154 is formed. For example, the conductive lines 114 may route electrical signals in a direction in and out of the page from the perspective of FIG. 1. The conductive vias 112 may be arranged to route electrical signals in a direction of a plane that is substantially perpendicular to the surface of the substrate 152 upon which the device layer 154 is formed. In some embodiments, the conductive vias 112 may electrically couple conductive lines 114 of different interconnect layers 158 and 162 together.

The interconnect layers 158 and 162 may include a dielectric material 124 disposed between the interconnect structures, as shown in FIG. 1. In some embodiments, the dielectric material 124 disposed between the interconnect structures in different ones of the interconnect layers 158 and 162 may have different compositions; in other embodiments, the composition of the dielectric material 124 between different interconnect layers 158 and 162 may be the same.

A first interconnect layer 158 (referred to as Metal 1 or “M1”) may be formed directly on the device layer 154. In some embodiments, the first interconnect layer 158 may include conductive lines 114 and/or conductive vias 112, as shown. The conductive lines 114 of the first interconnect layer 158 may be coupled with contacts (e.g., the S/D contacts 156) of the device layer 154.

A second interconnect layer 162 (referred to as Metal 2 or “M2”) may be formed directly on the first interconnect layer 158. In some embodiments, the second interconnect layer 162 may include conductive vias 112 to couple the conductive lines 114 of the second interconnect layer 162 with the conductive lines 114 of the first interconnect layer 158. Although the conductive lines 114 and the conductive vias 112 are structurally delineated with a line within each interconnect layer (e.g., within the second interconnect layer 162) for the sake of clarity, the conductive lines 114 and the conductive vias 112 may be structurally and/or materially contiguous (e.g., simultaneously filled during a dual-damascene process) in some embodiments.

Additional interconnect layers may be formed in succession on the second interconnect layer 162 according to similar techniques and configurations described in connection with the first interconnect layer 158 or the second interconnect layer 162.

The electronic device 150 may include a solder resist material 164 (e.g., polyimide or similar material) and one or more bond pads 166 formed on the interconnect layers. The bond pads 166 may be electrically coupled with the interconnect structures and may route the electrical signals of the memory cell 160 to other external devices. For example, solder bonds may be formed on the one or more bond pads 166 to mechanically and/or electrically couple a chip including the electronic device 150 with another component (e.g., a circuit board). The electronic device 150 may include other structures to route the electrical signals from the interconnect layers than depicted in other embodiments. For example, the bond pads 166 may be replaced by or may further include other analogous features (e.g., posts) that route electrical signals to external components.

As noted above, the electronic device 150 may include an MFMD 100 electrically coupled to a transistor 110, forming a memory cell 160. The MFMD 100 is illustrated as being included in the second interconnect layer 162, but the MFMD 100 may be located in any suitable interconnect layer or other portion of the electronic device 150.

The MFMD 100 of FIG. 1 may include an active metal electrode 102, a low work function diffusion barrier (LWFDB) 104, an electrolyte 106, and an inert metal electrode 108. As used herein, a diffusion barrier has a “low work function” if the work function of the diffusion barrier is less than the work function of the active metal electrode. The LWFDB 104 may be disposed between the active metal electrode 102 and the electrolyte 106, and the electrolyte 106 may be disposed between the LWFDB 104 and the inert metal electrode 108. In the embodiment illustrated in FIG. 1, the active metal electrode 102 may be electrically coupled to an S/D region 118 of the transistor 110 (e.g., through one or more conductive vias 112, conductive lines 114, and S/D contacts 156), and may provide the “bottom electrode” of the MFMD 100, electrically coupled between the transistor 110 and the inert metal electrode 108 of the MFMD 100. In other embodiments, the MFMD 100 illustrated in FIG. 1 may be oriented “upside down” so that the inert metal electrode 108 is electrically coupled between the transistor 110 and the active metal electrode 102; in such embodiments, the LWFDB 104 is still disposed between the active metal electrode 102 and the electrolyte 106, and the electrolyte 106 is still disposed between the LWFDB 104 and the inert metal electrode 108.

The active metal electrode 102 may be an electrochemically active metal with high solubility in solid electrolytes, such as copper, silver, or gold, or alloys of these materials. In particular, the material of the active metal electrode 102 may have high solubility in the electrolyte 106 so as to readily form metal filaments during operation. Note that “electrochemically active” is a material property of the active metal electrode 102, and thus the MFMD 100 need not be in operation for a metal of the active metal electrode 102 to be “electrochemically active.”

The electrolyte 106 may be a solid electrolyte, and may take any suitable form. In some embodiments, the electrolyte 106 may be an oxide, such as aluminum oxide or hafnium oxide. In some embodiments, the electrolyte 106 may be silicon oxide. In some embodiments, the electrolyte 106 may be a multicomponent alloy including group IV and VI elements, such as germanium sulfide or silicon telluride. In some embodiments, the electrolyte 106 may be a multilayer oxide formed by, for example, physical vapor deposition (PVD).

The inert metal electrode 108 of the MFMD 100 may be formed of any suitable inert metal. For example, in some embodiments, the inert metal electrode 108 may be formed of iridium, palladium, platinum, or ruthenium, or nitrides of more reactive metals, such as titanium nitride or tantalum nitride, for example. In some embodiments, the inert metal electrode 108 may be formed by PVD (e.g., sputtering) or atomic layer deposition (ALD).

The LWFDB 104 may include any suitable material having a lower work function than the material of the active metal electrode 102. For example, in some embodiments in which the active metal electrode 102 is copper or a copper alloy, the LWFDB 104 may be n-doped silicon carbide (e.g., as discussed in the example above), lanthanum boride (e.g., lanthanum hexaboride), or a lanthanum-tantalum alloy.

The inclusion of a lower work function material between the active metal electrode 102 and the electrolyte 106 may lower the total resistance of the MFMD 100 and decrease the forming voltage. FIG. 2 illustrates an example energy profile along the MFMD 100, with the inert metal electrode (IME) 108 on the far left and the active metal electrode (AME) 102 on the far right. Without the presence of the LWFDB 104 between the electrolyte 106 and the active metal electrode 102, the electric field is small in the electrolyte 106 and energy profile along the electrolyte 106 may remain close to the value 180 (the value of the conduction band barrier between the active metal electrode 102 and the electrolyte 106) across the entirety of the electrolyte 106 (as indicated by the dashed line). However, the presence of the LWFDB 104 may drop the energy level 182 at the interface between the electrolyte 106 and the LWFDB 104 to the value of the conduction band barrier between the LWFDB 104 and the electrolyte 106 (less than the conduction band barrier between the active metal electrode 102 and the electrolyte 106), as illustrated in FIG. 2. This change in the energy profile may make it easier for carriers to “tunnel” through this energy barrier during operation of the MFMD 100, decreasing the resistance of the MFMD 100. FIG. 2 also illustrates a smaller peak 184 in the energy profile at the interface between the LWFDB 104 and the active metal electrode 102. This smaller peak 184 may reflect Schottky barrier resistance, and the increased resistance that it causes may be significantly smaller than the decrease in resistance gained by including the LWFDB 104 between the electrolyte 106 and the active metal electrode 102. Additionally, because lower total resistance of an MFMD 100 may be associated with lower forming voltage, the forming voltage of the MFMDs 100 disclosed herein may be less than the forming voltage of an MFMD lacking an LWFDB 104.

For example, in some embodiments in which the active metal electrode 102 is copper, the LWFDB 104 is silicon carbide doped with an n-type material at a doping concentration of 2×10²⁰/cm³, and the electrolyte 106 is porous silicon dioxide, the energy profile may drop from a value 180 of approximately 3.75 eV (the conduction band barrier between copper and porous silicon dioxide) to a energy level 182 of approximately 2.47 eV (the conduction band barrier between the n-doped silicon carbide and porous silicon dioxide). The peak 184 due to Schottky barrier resistance may have a magnitude of approximately 1.5 eV. The total resistance of such an MFMD 100 may be less than the total resistance of an MFMD lacking such an LWFDB 104 by a factor of approximately 1000.

The MFMDs disclosed herein, including low work function diffusion barriers, may provide performance improvements over conventional memory devices. Some conventional memory devices, for example, may include a chemical barrier layer disposed between the active metal and the electrolyte to mitigate diffusion of the active metal into the electrolyte. The materials used for such barriers (e.g., titanium nitride, tantalum, or tungsten) have not provided the beneficial energy profile discussed above, and thus memory devices including such conventional barriers may not be able to achieve desirably low resistances and forming voltages.

In some embodiments, the LWFDB 104 may also have a lower solubility in the electrolyte 106 than the active metal electrode 102; this may help the LWFDB 104 serve as an effective diffusion barrier, mitigating the diffusion of the material of the active metal electrode 102 into the electrolyte 106.

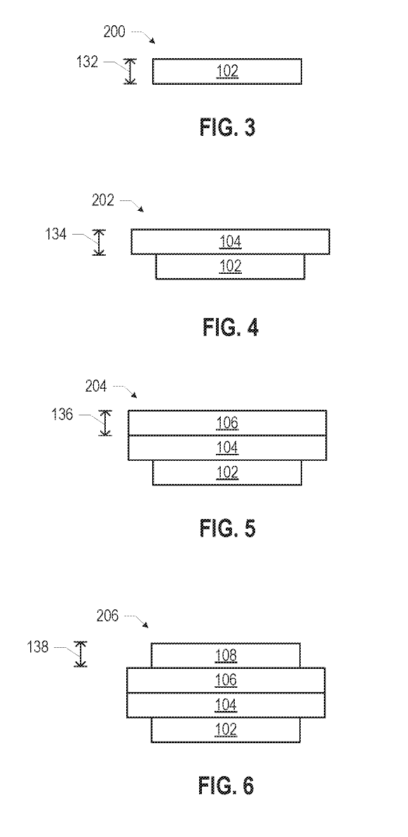

The MFMDs 100 disclosed herein may be formed using any suitable technique. For example, FIGS. 3-6 illustrate various example stages in the manufacture of the MFMD 100 of FIG. 1, in accordance with various embodiments. The order of the operations illustrated in FIGS. 3-6 may be reversed to form an MFMD 100 that is flipped “upside down” from the orientation illustrated in FIG. 1. Any suitable patterning techniques may be used to control the shape of the components of the MFMD 100 during manufacture (e.g., semi-additive techniques, subtractive techniques, or other techniques), and are thus not discussed further herein.

FIG. 3 is a side cross-sectional view of an assembly 200 subsequent to forming an active metal electrode 102. The active metal electrode 102 of the assembly 200 may take any of the forms disclosed herein. The active metal electrode 102 may be formed as part of an interconnect layer, as discussed above with reference to FIG. 1, and may be in conductive contact with an S/D region 118 of a transistor 110 (e.g., through one or more conductive lines and/or vias). In some embodiments, the transistor 110 may advantageously be a PMOS transistor; when the MFMD 100 is flipped “upside down” and the inert metal electrode 108 serves as the “bottom” electrode, the transistor 110 may advantageously be an NMOS transistor. In some embodiments, the active metal electrode 102 may be formed by PVD (e.g., sputtering). The active metal electrode 102 may have a thickness 132 that may take any suitable value. For example, the thickness 132 may be between 3 and 20 nanometers. In some embodiments (e.g., when the thickness 132 is between 3 and 20 nanometers, or otherwise small), an additional layer of “dummy” conductive material may be deposited before the active metal electrode 102 to form a bilayer structure; such a structure may meet integration requirements of devices like that shown in FIG. 1.

FIG. 4 is a side cross-sectional view of an assembly 202 subsequent to forming an LWFDB 104 on the active metal electrode 102 of the assembly 200 (FIG. 3). The LWFDB 104 may take any of the forms disclosed herein. In some embodiments, the LWFDB 104 may be formed by ALD or PVD techniques, such as reactive sputtering, pulsed DC sputtering, or RF sputtering. The LWFDB 104 may have a thickness 134 that may take any suitable value. For example, the thickness 134 may be between 1 and 5 nanometers.

FIG. 5 is a side cross-sectional view of an assembly 204 subsequent to forming an electrolyte 106 on the LWFDB 104 of the assembly 202 (FIG. 4). The electrolyte 106 may have a thickness 136 that may take any suitable value. For example, the thickness 136 may be between 3 and 10 nanometers. In some embodiments, the electrolyte 106 may be formed by ALD or PVD techniques, such as reactive sputtering, pulsed DC sputtering, or RF sputtering.

FIG. 6 is a side cross-sectional view of an assembly 206 subsequent to forming an inert metal electrode 108 on the electrolyte 106 of the assembly 204 (FIG. 5). The inert metal electrode 108 may take any of the forms disclosed herein. The thickness 138 of the inert metal electrode 108 may take the form of any of the embodiments of the thickness 132 of the active metal electrode 102. The assembly 206 may take the form of the MFMD 100 of FIG. 1.

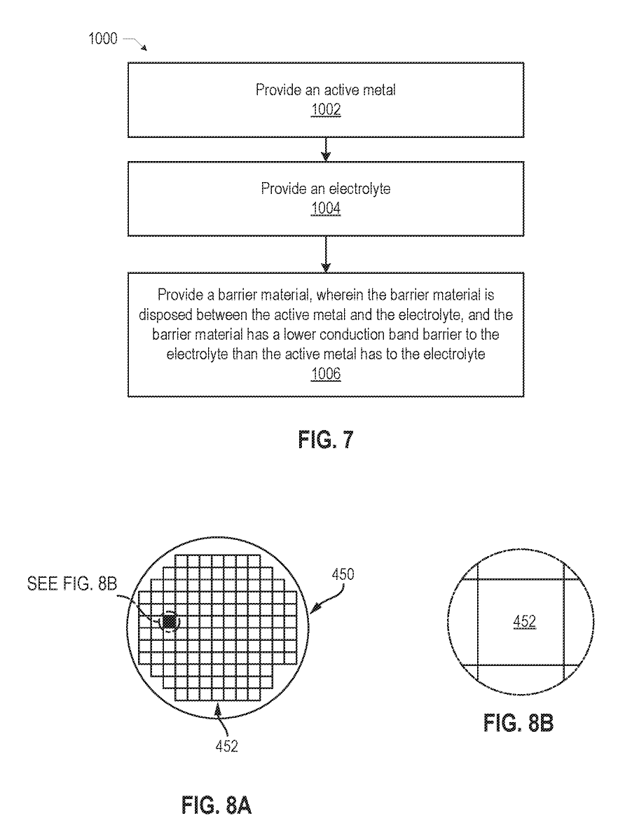

As noted above, any suitable techniques may be used to manufacture the MFMDs 100 disclosed herein. FIG. 7 is a flow diagram of an illustrative method 1000 of manufacturing an MFMD, in accordance with various embodiments. Although the operations discussed below with reference to the method 1000 are illustrated in a particular order and depicted once each, these operations may be repeated or performed in a different order (e.g., in parallel), as suitable. Additionally, various operations may be omitted, as suitable. Various operations of the method 1000 may be illustrated with reference to one or more of the embodiments discussed above, but the method 1000 may be used to manufacture any suitable MFMD (including any suitable ones of the embodiments disclosed herein).

At 1002, an active metal may be provided. For example, an active metal electrode 102 may be formed (e.g., as discussed above with reference to FIGS. 1 and 3).

At 1004, an electrolyte may be provided. For example, an electrolyte 106 may be formed (e.g., as discussed above with reference to FIGS. 1 and 5).

At 1006, a barrier material may be provided. The barrier material may be disposed between the active metal and the electrolyte, and the barrier material may have a lower conduction band barrier to the electrolyte than the active metal has to the electrolyte. For example, a LWFDB 104 may be formed (e.g., as discussed above with reference to FIGS. 1 and 4). The LWFDB 104 may have a lower conduction band barrier to the electrolyte 106 than the active metal of the active metal electrode 102 has to the electrolyte 106.

The MFMDs 100 and memory cells 160 disclosed herein may be included in any suitable electronic device. FIGS. 8A-B are top views of a wafer 450 and dies 452 that may be formed from the wafer 450; the dies 452 may include any of the MFMDs 100 or memory cells 160 disclosed herein. The wafer 450 may include semiconductor material and may include one or more dies 452 having integrated circuit elements (e.g., MFMDs 100 and transistors 110) formed on a surface of the wafer 450. Each of the dies 452 may be a repeating unit of a semiconductor product that includes any suitable device (e.g., the electronic device 150). After the fabrication of the semiconductor product is complete, the wafer 450 may undergo a singulation process in which each of the dies 452 is separated from one another to provide discrete “chips” of the semiconductor product. A die 452 may include one or more MFMDs 100 or memory cells 160 and/or supporting circuitry to route electrical signals to the MFMDs 100 or memory cells 160 (e.g., interconnects including conductive vias 112 and lines 114), as well as any other integrated circuit (IC) components. In some embodiments, the wafer 450 or the die 452 may include other memory devices, logic devices (e.g., AND, OR, NAND, or NOR gates), or any other suitable circuit element. Multiple ones of these devices may be combined on a single die 452. For example, a memory array formed by multiple memory devices (e.g., multiple MFMDs 100) may be formed on a same die 452 as a processing device (e.g., the processing device 2002 of FIG. 10) or other logic that is configured to store information in the memory devices or execute instructions stored in the memory array.

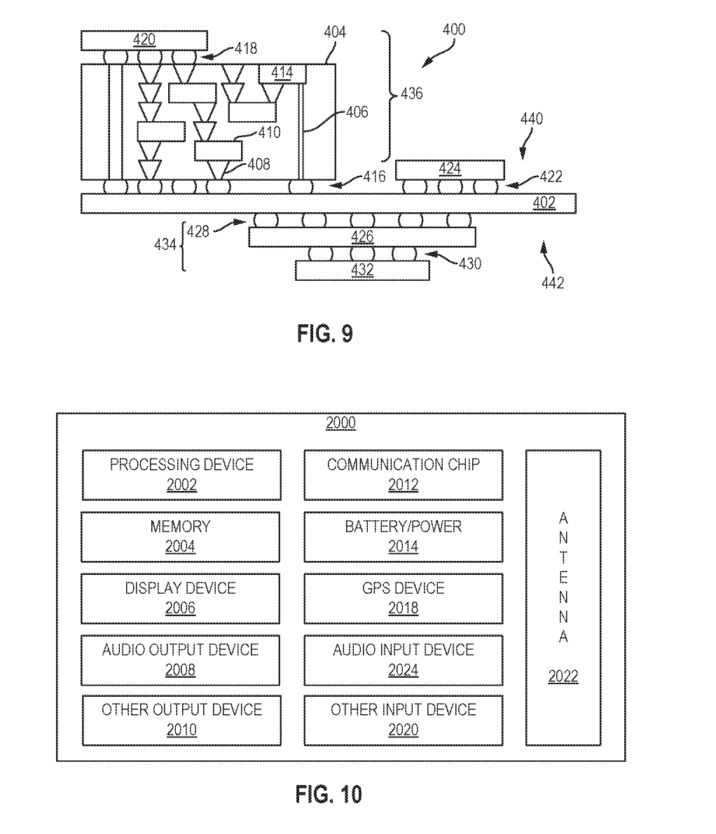

FIG. 9 is a cross-sectional side view of a device assembly 400 that may include any of the MFMDs 100 or memory cells 160 disclosed herein included in one or more packages. A “package” may refer to an electronic component that includes one or more IC devices that are structured for coupling to other components; for example, a package may include a die coupled to a package substrate that provides electrical routing and mechanical stability to the die. The device assembly 400 includes a number of components disposed on a circuit board 402. The device assembly 400 may include components disposed on a first face 440 of the circuit board 402 and an opposing second face 442 of the circuit board 402; generally, components may be disposed on one or both faces 440 and 442.

In some embodiments, the circuit board 402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 402. In other embodiments, the circuit board 402 may be a package substrate or flexible board.

The device assembly 400 illustrated in FIG. 9 includes a package-on-interposer structure 436 coupled to the first face 440 of the circuit board 402 by coupling components 416. The coupling components 416 may electrically and mechanically couple the package-on-interposer structure 436 to the circuit board 402, and may include solder balls, male and female portions of a socket, an adhesive, an underfill material, and/or any other suitable electrical and/or mechanical coupling structure.

The package-on-interposer structure 436 may include a package 420 coupled to an interposer 404 by coupling components 418. The coupling components 418 may take any suitable form for the application, such as the forms discussed above with reference to the coupling components 416. Although a single package 420 is shown in FIG. 9, multiple packages may be coupled to the interposer 404; indeed, additional interposers may be coupled to the interposer 404. The interposer 404 may provide an intervening substrate used to bridge the circuit board 402 and the package 420. The package 420 may include one or more MFMDs 100 or memory cells 160, for example. Generally, the interposer 404 may spread a connection to a wider pitch or reroute a connection to a different connection. For example, the interposer 404 may couple the package 420 (e.g., a die) to a ball grid array (BGA) of the coupling components 416 for coupling to the circuit board 402. In the embodiment illustrated in FIG. 9, the package 420 and the circuit board 402 are attached to opposing sides of the interposer 404; in other embodiments, the package 420 and the circuit board 402 may be attached to a same side of the interposer 404. In some embodiments, three or more components may be interconnected by way of the interposer 404.

The interposer 404 may be formed of an epoxy resin, a fiberglass-reinforced epoxy resin, a ceramic material, or a polymer material such as polyimide. In some embodiments, the interposer 404 may be formed of alternate rigid or flexible materials that may include the same materials described above for use in a semiconductor substrate, such as silicon, germanium, and other group III-V and group IV materials. The interposer 404 may include metal interconnects 408 and vias 410, including but not limited to through-silicon vias (TSVs) 406. The interposer 404 may further include embedded devices 414, including both passive and active devices. Such devices may include, but are not limited to, capacitors, decoupling capacitors, resistors, inductors, fuses, diodes, transformers, sensors, electrostatic discharge (ESD) devices, and memory devices (e.g., the MFMDs 100 or the memory cells 160). More complex devices such as radio-frequency (RF) devices, power amplifiers, power management devices, antennas, arrays, sensors, and microelectromechanical systems (MEMS) devices may also be formed on the interposer 404. The package-on-interposer structure 436 may take the form of any of the package-on-interposer structures known in the art.

The device assembly 400 may include a package 424 coupled to the first face 440 of the circuit board 402 by coupling components 422. The coupling components 422 may take the form of any of the embodiments discussed above with reference to the coupling components 416, and the package 424 may take the form of any of the embodiments discussed above with reference to the package 420. The package 424 may include one or more MFMDs 100 or memory cells 160, for example.

The device assembly 400 illustrated in FIG. 9 includes a package-on-package structure 434 coupled to the second face 442 of the circuit board 402 by coupling components 428. The package-on-package structure 434 may include a package 426 and a package 432 coupled together by coupling components 430 such that the package 426 is disposed between the circuit board 402 and the package 432. The coupling components 428 and 430 may take the form of any of the embodiments of the coupling components 416 discussed above, and the packages 426 and 432 may take the form of any of the embodiments of the package 420 discussed above. Each of the packages 426 and 432 may include one or more MFMDs 100 or memory cells 160, for example.

FIG. 10 is a block diagram of an example computing device 2000 that may include any of the MFMDs 100 or memory cells 160 disclosed herein. A number of components are illustrated in FIG. 10 as included in the computing device 2000, but any one or more of these components may be omitted or duplicated, as suitable for the application. In some embodiments, some or all of the components included in the computing device 2000 may be attached to one or more printed circuit boards (e.g., a motherboard). In some embodiments, various ones of these components may be fabricated onto a single system-on-a-chip (SoC) die. Additionally, in various embodiments, the computing device 2000 may not include one or more of the components illustrated in FIG. 10, but the computing device 2000 may include interface circuitry for coupling to the one or more components. For example, the computing device 2000 may not include a display device 2006, but may include display device interface circuitry (e.g., a connector and driver circuitry) to which a display device 2006 may be coupled. In another set of examples, the computing device 2000 may not include an audio input device 2024 or an audio output device 2008, but may include audio input or output device interface circuitry (e.g., connectors and supporting circuitry) to which an audio input device 2024 or audio output device 2008 may be coupled.

The computing device 2000 may include a processing device 2002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2002 may interface with one or more of the other components of the computing device 2000 (e.g., the communication chip 2012 discussed below, the display device 2006 discussed below, etc.) in a conventional manner. The processing device 2002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 2000 may include a memory 2004, which may itself include one or more memory devices such as volatile memory (e.g., dynamic random access memory (DRAM)), nonvolatile memory (e.g., read-only memory (ROM)), flash memory, solid state memory, and/or a hard drive. The memory 2004 may include one or more MFMDs 100 or memory cells 160. In some embodiments, the memory 2004 may include memory that shares a die with the processing device 2002. This memory may be used as cache memory and may include embedded dynamic random access memory (eDRAM) or spin transfer torque magnetic random-access memory (STT-MRAM).

In some embodiments, the computing device 2000 may include a communication chip 2012 (e.g., one or more communication chips). For example, the communication chip 2012 may be configured for managing wireless communications for the transfer of data to and from the computing device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2012 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2012 may operate in accordance with other wireless protocols in other embodiments. The computing device 2000 may include an antenna 2022 to facilitate wireless communications and/or to receive other wireless communications (such as AM or FM radio transmissions).

In some embodiments, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as GPS, EDGE, GPRS, CDMA, WiMAX, LTE, EV-DO, or others. In some embodiments, a first communication chip 2012 may be dedicated to wireless communications, and a second communication chip 2012 may be dedicated to wired communications.

The computing device 2000 may include battery/power circuitry 2014. The battery/power circuitry 2014 may include one or more energy storage devices (e.g., batteries or capacitors) and/or circuitry for coupling components of the computing device 2000 to an energy source separate from the computing device 2000 (e.g., AC line power).

The computing device 2000 may include a display device 2006 (or corresponding interface circuitry, as discussed above). The display device 2006 may include any visual indicators, such as a heads-up display, a computer monitor, a projector, a touchscreen display, a liquid crystal display (LCD), a light-emitting diode display, or a flat panel display, for example.

The computing device 2000 may include an audio output device 2008 (or corresponding interface circuitry, as discussed above). The audio output device 2008 may include any device that generates an audible indicator, such as speakers, headsets, or earbuds, for example.

The computing device 2000 may include an audio input device 2024 (or corresponding interface circuitry, as discussed above). The audio input device 2024 may include any device that generates a signal representative of a sound, such as microphones, microphone arrays, or digital instruments (e.g., instruments having a musical instrument digital interface (MIDI) output).

The computing device 2000 may include a global positioning system (GPS) device 2018 (or corresponding interface circuitry, as discussed above). The GPS device 2018 may be in communication with a satellite-based system and may receive a location of the computing device 2000, as known in the art.

The computing device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The computing device 2000 may include an other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The following paragraphs provide various examples of the embodiments disclosed herein.

Example 1 is a device, including: an electrode of a metal filament memory device (MFMD), the electrode including an electrochemically active metal; an electrolyte; and a barrier material disposed between the electrode and the electrolyte, wherein the barrier material has a lower work function than the electrode.

Example 2 may include the subject matter of Example 1, and may further specify that the barrier material has a lower solubility in the electrolyte than the electrode has in the electrolyte.

Example 3 may include the subject matter of any of Examples 1-2, and may further specify that the electrode is copper or a copper alloy.

Example 4 may include the subject matter of Example 3, and may further specify that the barrier material is lanthanum boride.

Example 5 may include the subject matter of Example 3, and may further specify that the barrier material is a lanthanum-tantalum alloy.

Example 6 may include the subject matter of Example 3, and may further specify that the barrier material is n-doped silicon carbide.

Example 7 may include the subject matter of any of Examples 1-6, and may further specify that the electrolyte is silicon oxide.

Example 8 may include the subject matter of any of Examples 1-7, and may further specify that the electrolyte has a thickness between 3 and 10 nanometers.

Example 9 may include the subject matter of any of Examples 1-8, and may further specify that the barrier material has a thickness between 1 and 5 nanometers.

Example 10 may include the subject matter of any of Examples 1-9, wherein the electrode is a first electrode, and the device further includes a second electrode of the MFMD, wherein the second electrode includes an electrochemically inert metal, and the electrolyte is disposed between the barrier material and the second electrode.

Example 11 may include the subject matter of any of Examples 1-10, and may further include a transistor having a source/drain region coupled to the MFMD.

Example 12 may include the subject matter of Example 11, and may further specify that the transistor is an n-type metal oxide semiconductor (NMOS) transistor and the electrolyte is coupled between the electrode and the source/drain region.

Example 13 may include the subject matter of Example 11, and may further specify that the transistor is a p-type metal oxide semiconductor (PMOS) transistor and the electrode is coupled between the electrolyte and the source/drain region.

Example 14 is a method of manufacturing a memory cell, including: forming a layer of an electrochemically active metal; forming a layer of an electrolyte; and forming a layer of a barrier material; wherein the layer of the barrier material is disposed between the layer of the electrochemically active metal and the layer of the electrolyte, and the barrier material has a lower conduction band barrier to the electrolyte than the electrochemically active metal has to the electrolyte.

Example 15 may include the subject matter of Example 14, and may further specify that the layer of electrochemically active metal is formed before the layer of the electrolyte is formed.

Example 16 may include the subject matter of Example 14, and may further specify that the layer of electrochemically active metal is formed after the layer of the electrolyte is formed.

Example 17 may include the subject matter of any of Examples 14-16, and may further specify that forming the layer of the electrochemically active metal includes physical vapor deposition of the electrochemically active metal.

Example 18 may include the subject matter of any of Examples 14-17, and may further specify that forming the layer of the barrier material includes sputtering the barrier material.

Example 19 is a method of operating a memory cell, including: controlling current to a metal filament memory device (MFMD), through a transistor, to set the MFMD in a low resistance state, wherein the MFMD includes an electrochemically active metal, an electrolyte, and a barrier material disposed between the electrochemically active metal and the electrolyte; and controlling current to the MFMD, through the transistor, to reset the MFMD to a high resistance state; wherein the barrier material has a lower work function than the electrochemically active metal.

Example 20 may include the subject matter of Example 19, and may further specify that the transistor is an n-type metal oxide semiconductor (NMOS) transistor, and the electrolyte is coupled between the electrochemically active metal and a source/drain region of the NMOS transistor.

Example 21 may include the subject matter of Example 19, and may further specify that the transistor is a p-type metal oxide semiconductor (PMOS) transistor, and the electrochemically active metal is coupled between the electrolyte and a source/drain region of the PMOS transistor.

Example 22 may include the subject matter of any of Examples 19-21, and may further specify that the electrochemically active metal is copper or silver.

Example 23 is a computing device, including: a circuit board; a processing device coupled to the circuit board; and a memory device coupled to the processing device, wherein the memory device includes a metal filament memory device (MFMD), the MFMD includes an electrochemically active metal, an electrolyte, and a barrier material, the barrier material is disposed between the electrochemically active metal and the electrolyte, and the barrier material has a lower conduction band barrier to the electrolyte than the electrochemically active metal has to the electrolyte.

Example 24 may include the subject matter of Example 23, wherein the electrolyte is silicon dioxide.

Example 25 may include the subject matter of any of Examples 23-24, and may further specify that the electrochemically active metal is copper or a copper alloy.

1. A device, comprising:
an electrode of a metal filament memory device (MFMD), the electrode including an electrochemically active metal;
an electrolyte; and
a barrier material disposed between the electrode and the electrolyte, wherein the barrier material has a lower work function than the electrode.

2. The device of claim 1, wherein the barrier material has a lower solubility in the electrolyte than the electrode has in the electrolyte.

3. The device of claim 1, wherein the electrode is copper or a copper alloy.

4. The device of claim 3, wherein the barrier material is lanthanum boride.

5. The device of claim 3, wherein the barrier material is a lanthanum-tantalum alloy.

6. The device of claim 3, wherein the barrier material is n-doped silicon carbide.

7. The device of any of claims 1-6, wherein the electrolyte is silicon oxide.

8. The device of any of claims 1-6, wherein the electrolyte has a thickness between 3 and 10 nanometers.

9. The device of any of claims 1-6, wherein the barrier material has a thickness between 1 and 5 nanometers.

10. The device of any of claims 1-6, wherein the electrode is a first electrode, and the device further includes:
a second electrode of the MFMD, the second electrode including an electrochemically inert metal;
wherein the electrolyte is disposed between the barrier material and the second electrode.

11. The device of any of claims 1-6, further comprising:
a transistor having a source/drain region coupled to the MFMD.

12. The device of claim 11, wherein the transistor is an n-type metal oxide semiconductor (NMOS) transistor and the electrolyte is coupled between the electrode and the source/drain region.

13. The device of claim 11, wherein the transistor is a p-type metal oxide semiconductor (PMOS) transistor and the electrode is coupled between the electrolyte and the source/drain region.

14. A method of manufacturing a memory cell, including:
forming a layer of an electrochemically active metal;
forming a layer of an electrolyte; and
forming a layer of a barrier material;
wherein the layer of the barrier material is disposed between the layer of the electrochemically active metal and the layer of the electrolyte, and the barrier material has a lower conduction band barrier to the electrolyte than the electrochemically active metal has to the electrolyte.

15. The method of claim 14, wherein the layer of electrochemically active metal is formed before the layer of the electrolyte is formed.

16. The method of claim 14, wherein the layer of electrochemically active metal is formed after the layer of the electrolyte is formed.

17. The method of any of claims 14-16, wherein forming the layer of the electrochemically active metal includes physical vapor deposition of the electrochemically active metal.

18. The method of any of claims 14-16, wherein forming the layer of the barrier material includes sputtering the barrier material.

19. A method of operating a memory cell, comprising:
controlling current to a metal filament memory device (MFMD), through a transistor, to set the MFMD in a low resistance state, wherein the MFMD includes an electrochemically active metal, an electrolyte, and a barrier material disposed between the electrochemically active metal and the electrolyte; and
controlling current to the MFMD, through the transistor, to reset the MFMD to a high resistance state;
wherein the barrier material has a lower work function than the electrochemically active metal.

20. The method of claim 19, wherein the transistor is an n-type metal oxide semiconductor (NMOS) transistor, and the electrolyte is coupled between the electrochemically active metal and a source/drain region of the NMOS transistor.

21. The method of claim 19, wherein the transistor is a p-type metal oxide semiconductor (PMOS) transistor, and the electrochemically active metal is coupled between the electrolyte and a source/drain region of the PMOS transistor.

22. The method of any of claims 19-21, wherein the electrochemically active metal is copper or silver.

23. A computing device, comprising:
a circuit board;
a processing device coupled to the circuit board; and
a memory device coupled to the processing device, wherein:
the memory device includes a metal filament memory device (MFMD),
the MFMD includes an electrochemically active metal, an electrolyte, and a barrier material,
the barrier material is disposed between the electrochemically active metal and the electrolyte, and
the barrier material has a lower conduction band barrier to the electrolyte than the electrochemically active metal has to the electrolyte.

24. The computing device of claim 23, wherein the electrolyte is silicon dioxide.

25. The computing device of any of claims 23-24, wherein the electrochemically active metal is copper or a copper alloy.
